(19) United States
(12) Patent Application Publication
(10) Pub. No.: US 2024/0255751 A1
(43) Pub. Date: Aug. 1, 2024

(54) Stress Optic Tuners for Waveguide-Based Devices

(71) Applicants: The Regents of the University of California, Oakland, CA (US); United States Army, Adelphi, MD (US)

(72) Inventors: Daniel J. Blumenthal, Santa Barbara, CA (US); Jiawei Wang, Goleta, CA (US); Kaikai Liu, Santa Barbara, CA (US); Ryan Q. Rudy, Adelphi, MD (US)

(73) Assignees: The Regents of the University of California, Oakland, CA (US); United States Army, Adelphi, MD (US)

(21) Appl. No.: 18/485,173

(22) Filed: Oct. 11, 2023

Related U.S. Application Data
(60) Provisional application No. 63/381,894, filed on Nov. 1, 2022.
(60) Provisional application No. 63/379,829, filed on Oct. 17, 2022.
(60) Provisional application No. 63/379,112, filed on Oct. 11, 2022.

(51) Int. Cl. G02B 26/08; G02B 6/42; H10N 30/20; H10N 30/853; H10N 30/87

(52) U.S. Cl. CPC G02B 26/0875; G02B 6/4204; H10N 30/206; H10N 30/8554; H10N 30/877

(57) ABSTRACT

Disclosed herein is a stress optical modulator. The modulator include a circular piezo-electric actuator; and a ring waveguide separated from the circular piezo-electric actuator by a top cladding layer. The circular piezo-electric actuator may be offset from the ring waveguide such that a first circular portion of the circular piezo-electric actuator is located on the outside of the ring waveguide and a second circular portion of the circular piezo-electric actuator is located on the inside of the ring waveguide. The circular piezo-electric actuator may be configured to change the guiding properties of the ring waveguide based on the voltage applied to the circular piezo-electric actuator by inducing strain through the top cladding layer to change the optical properties of the ring waveguide.

### CROSS-REFERENCE TO RELATED APPLICATIONS

This application claims the benefit of and priority under 35 U.S.C. § 119(e) to U.S. Provisional Patent Application Ser. No. 63/379,112 entitled “Stress Optic Tuners and Modulators for Ultra-Low Loss Planar Photonic Integration and Control Functions” and filed Oct. 11, 2022, U.S. Provisional Patent Application Ser. No. 63/381,894 entitled “Stress Optic Tuners and Modulators for Ultra-Low Loss Planar Photonic Integration and Control Functions” and filed Nov. 1, 2022, and U.S. Provisional Patent Application Ser. No. 63/379,829, entitled “Integrated Stress Optic Modulated Low Loss Waveguides” and filed Oct. 17, 2022, which are incorporated herein by reference in their entirety for all purposes.

### STATEMENT OF FEDERALLY SPONSORED RESEARCH

This invention was made with government support under Grant (or Contract) No. 1745612, awarded by the National Science Foundation and under Grant (or Contract) No. W911NF-22-2-0056, awarded by United States Army. The government has certain rights in the invention.

### FIELD OF THE INVENTION

The present invention generally relates to stress optic tuners utilized in waveguide based devices including modulators, phase shifters, ring resonators, interferometers, and other controllable waveguide based devices.

### BACKGROUND

Photonic integrated circuits can provide benefit to a wide range of applications by reducing their size, weight, power consumption, and cost as well as improving reliability, scalability, performance, and manufacturability, similar to the benefits microelectronics has brought. Such applications include optical and fiber communications, data centers interconnects and cloud communications and computing, optical gyroscopes and laser-based position and navigation, Light Detection and Ranging (LIDAR), atomic and optical clocks and timekeeping, quantum sensors and computing, quantum communications, space-based applications, and fundamental physics experiments.

Photonic integrated circuits, provide the ability to co-locate, at the chip-scale, a wide array of interconnected components and functions required by these applications, including lasers, modulators, detectors, and other optical components, sub-systems, and systems, that normally occupy tables, racks and equipment boxes. Components and integrated photonic circuits may be able to support design and operation over a broad range of performance specifications including operating at optical frequencies from the ultra-violet, through the visible, and into the infrared. Additionally, many applications include that the waveguides, the optical wires that route photons, and other components on these circuits, operate with very low optical loss and with low power consumption. In order to reduce cost and provide manufacturable solutions, these ultra-low loss, wavelength independent, low-power, integrated circuits may be fabricated using processes that are compatible with standard wafer-scale CMOS foundry processes.

In addition to low optical loss, almost all applications include tuning and modulation of lasers, optical components, and optical signals. Examples include tuning of laser wavelengths and optical filters, modulation of the phase and/or amplitude of an optical signal, tuning and modulation of optical frequency combs (OFCs) and modulation of an optical signal to perform control functions such as locking a laser to an optical reference cavity, atom, or ion or communications channel control signals. It may be advantageous that the mechanisms used to accomplish tuning and modulation be compatible with the optical waveguides and photonic waveguide, including transparency to, or independence of, the optical wavelength and the ability to modulate and tune without affecting the low optical losses and other desirable attributes of the optical waveguide and photonic integrated circuit.

Modulation in general may be achieved by actuating the optical waveguides, typically using one of several physical mechanisms including stress-optic, electro-optic, and thermal. These mechanisms change the physical characteristics of the waveguides, for example the optical index of refraction or the physical length. A major challenge in photonic integrated circuits is to realize optical actuation for tuning and modulation that can operate at any wavelength, does not affect the optical losses, is compatible with the planar fabrication methods of wafer-scale CMOS foundry compatible processes, operates with low power consumption, and can provide DC static tuning as well as modulation bandwidths that support DC out to multiple MHz and even out to GHz frequencies for control and other applications. Thermal tuning techniques may provide independence to wavelength and compatibility with planar fabrication processes, but may lead to tradeoffs in optical losses and tuning efficiency, have limited modulation bandwidth, and are highly power consuming. Electrooptic techniques may have higher optical losses, have limited operating bandwidth and dependence on wavelength, and can be power consuming. Stress-optic actuation can provide many benefits including preserving low loss across all operating wavelengths, compatibility with planar wafer-scale CMOS foundry compatible fabrication, and DC to 10 s to 100 s MHz and higher bandwidth modulation and tuning.

### SUMMARY OF THE INVENTION

In some aspects, the techniques described herein relate to a stress-optical modulator including: a circular piezo-electric actuator; and a ring waveguide separated from the circular piezo-electric actuator by a top cladding layer, wherein the circular piezo-electric actuator is offset from the ring waveguide such that a first circular portion of the circular piezo-electric actuator is located on the outside of the ring waveguide and a second circular portion of the circular piezo-electric actuator is located on the inside of the ring waveguide, wherein the circular piezo-electric actuator is configured to change the guiding properties of the ring waveguide based on the voltage applied to the circular piezo-electric actuator by inducing strain through the top cladding layer to change the optical properties of the ring waveguide.

In some aspects, the techniques described herein relate to a stress-optical modulator, wherein the piezo-electric actuator includes a piezo-electric material positioned between two electrodes.

In some aspects, the techniques described herein relate to a stress-optical modulator, wherein the piezo-electric material includes lead zirconate titanate (PZT) or aluminum nitride.

In some aspects, the techniques described herein relate to a stress-optical modulator, wherein the two electrodes include platinum.

In some aspects, the techniques described herein relate to a stress-optical modulator, wherein one of the two electrodes contact the top cladding layer.

In some aspects, the techniques described herein relate to a stress-optical modulator, wherein the inside edge of the first circular portion and the second circular portion is completely offset from all portions of the ring waveguide.

In some aspects, the techniques described herein relate to a stress-optical modulator, wherein the first circular portion and the second circular portion does not overlap with the ring waveguide in a direction perpendicular to a major extending direction of the ring waveguide.

In some aspects, the techniques described herein relate to a stress-optical modulator, further including: a substrate; and a bottom cladding layer positioned on the substrate, wherein the ring waveguide is supported by the bottom cladding layer.

In some aspects, the techniques described herein relate to a stress-optical modulator, wherein the ring waveguide has a refractive index which is higher than the top cladding layer and the bottom cladding layer.

In some aspects, the techniques described herein relate to a stress-optical modulator, wherein the top cladding layer has a refractive index which is different from the refractive index of the bottom cladding layer.

In some aspects, the techniques described herein relate to a stress-optical modulator, wherein the ring waveguide is connected through a bus waveguide to a laser.

In some aspects, the techniques described herein relate to a stress-optical modulator, wherein the ring waveguide is connected through one or more optical components to the laser.

In some aspects, the techniques described herein relate to a stress-optical modulator, wherein the ring waveguide and the bus waveguide includes a same material such that the ring waveguide and bus waveguide include a high quality factor (Q) resonator.

In some aspects, the techniques described herein relate to a stress-optical modulator, wherein the ring waveguide, the bus waveguide, and the laser are planar.

In some aspects, the techniques described herein relate to a stress-optical modulator, wherein the piezo-electric actuator covers less than 50% of the ring waveguide.

In some aspects, the techniques described herein relate to a stress-optical modulator, wherein the circular piezo-electric actuator is offset from the ring waveguide by an offset distance from 2 μm to 5 μm.

In some aspects, the techniques described herein relate to a stress-optical modulator, wherein an input signal to the piezo-electric actuator is a DC signal, an AC signal, or a broadband DC to AC signal.

In some aspects, the techniques described herein relate to a stress-optical modulator, wherein the ring waveguide includes a material selected from the group consisting of a material with a third order (Kerr) nonlinearity, a material with a second order nonlinearity, a material of with anomalous material and resonator dispersion, and a material of with normal material and resonator dispersion.

In some aspects, the techniques described herein relate to a stress-optical modulator, wherein the ring waveguide has a shape selected from the group consisting of: a ring resonator, a loop resonator, a coil resonator, and a racetrack resonator.

In some aspects, the techniques described herein relate to a stress-optical modulator, wherein the ring waveguide includes a material selected from the group consisting of: silicon nitride, tantalum pentoxide, alumina oxide, and aluminum nitride.

In some aspects, the techniques described herein relate to a stress-optical modulator, wherein the piezo-electric actuator includes PZT and the ring waveguide includes silicon nitride, and the modulator functions at a wavelength selected from the group consisting of: a visible wavelength range of approximately 400 nm to 750 nm, a near IR from 700 nm to 2500 nm, and a mid IR from 2.5 μm to 25 μm.

In some aspects, the techniques described herein relate to a stress-optical modulator, wherein the piezo-electric actuator includes PZT and the ring waveguide includes tantalum pentoxide or alumina oxide or aluminum nitride, and the modulator functions at a far-UV range from approximately 100 nm to 200 nm, a mid-UV from 200 nm to 300 nm, a near UV from 300 nm to 400 nm, and out to visible, near IR and mid-IR (400 nm to 2350 nm) and beyond.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The description will be more fully understood with reference to the following figures, which are presented as exemplary embodiments of the invention and should not be construed as a complete recitation of the scope of the invention, wherein:

FIGS. 1A through 1C illustrate a stress-optic modulator configuration in accordance with an embodiment of the invention.

FIG. 2A illustrates an example cross sectional schematic for a stress-optic modulator in accordance with an embodiment of the invention.

FIG. 2B illustrates an optical mode simulation of a PZT actuator model in accordance with an embodiment of the invention.

FIG. 2C illustrates stress distribution of a PZT actuator model in accordance with an embodiment of the invention.

FIG. 2D illustrates a PZT actuator model to simulate the offset distance in accordance with an embodiment of the invention.

FIG. 2E illustrates the effective index change as a function of PZT offset distance and PZT thickness in accordance with an embodiment.

FIG. 2F illustrates different quality (Q) factor and loss as a function of PZT offset distance in accordance with an embodiment.

FIG. 3 illustrates a cross section of a conventional stress-optic modulator configuration.

FIG. 4A illustrates the Q measurement of the resonator in accordance with an embodiment of the invention.

FIG. 4B illustrates the optical transmission spectrum of the static tuning of the modulator in accordance with an embodiment of the invention.

FIG. 4C illustrates the PZT hysteresis measured with reverse biasing in accordance with an embodiment of the invention.

FIG. 5A illustrates the frequency response in accordance with an embodiment of the invention.

FIGS. 5B and 5C illustrate RF output power of the fundamental and third order intermodulation distortion (IMD3) component as a function of RF input power of the ring modulator at about 1 MHz and about 10 MHz respectively in accordance with an embodiment.

FIG. 6 illustrates a PDH locking setup in accordance with an embodiment of the invention.

FIGS. 7A through 7C illustrate the performance of the modulator in the PDH locking application in accordance with an embodiment.

FIG. 8 illustrates the stress-optic modulator locked to the laser output using a PDH locking circuit in accordance with an embodiment.

FIGS. 9A and 9B illustrate the frequency response of the sinusoidal and step input signal respectively in accordance with an embodiment.

FIG. 10 illustrates PZT-actuated modulators for control functions in an external cavity laser (ECL) in accordance with an embodiment of the invention.

FIG. 11A is an example layout of a photonic device including a single stress-optic modulator in accordance with an embodiment of the invention.

FIG. 11B is an example of a photonic device including a single stress-optic modulator in accordance with an embodiment of the invention.

FIG. 12 is an example layout of a photonic device including two stress-optic modulators in accordance with an embodiment of the invention.

FIG. 13 is an example layout of a photonic device including three stress-optic modulators in accordance with an embodiment of the invention.

FIG. 14 is a layout of an example MZI modulator including a stress-optic modulator in accordance with an embodiment of the invention.

### DETAILED SUMMARY

Various embodiments of the invention include photonic integrated circuits. These photonic integrated circuits may include silicon nitride (Si₃N₄) waveguides as well as other waveguide types including tantalum pentoxide (Ta₂O₅), aluminum oxide (Al₂O₃), and aluminum nitride (AlN). Photonic integrated circuits including Si₃N₄ waveguides can deliver ultra-low waveguide losses and broad passive functionality across the visible into the mid-IR wavelength range in a planar wafer-scale, CMOS-foundry compatible and CMOS compatible processes. Si₃N₄ waveguides may provide the benefits of integration, such as low-cost, portability, low-power, scalability, and enhanced reliability to a wide range of applications including quantum information sciences and applications, quantum computing and sensing, quantum communications, optical atomic clocks, precision metrology, atomic, molecular and optical physics (AMO), microwave photonics, fiber optic precision frequency distribution, fiber optic communications and sensing, and energy efficient optical and fiber communications. One unique function of Si₃N₄ integrated photonic devices among these applications is optical actuation and modulation to perform tuning and control functions including wavelength shifting, sideband generation and sweep modulation, and phase shifting, with low optical insertion loss and modulation bandwidths from DC to 10 s of MHz and 100 s of MHz and higher.

Examples include laser locking to reference cavities and atomic transitions and optical channel tracking and transmission of control channels in fiber communications and laser noise reduction for microwave signal generation and signal processing. Conventionally, these systems use power-consuming bulk-optic electrooptic (EOM) and/or acousto-optic (AOM) modulators to implement control loops such as the Pound-Drever Hall (PDH) and proportional, integration and derivative (PID). Devices and functions such as tunable lasers, optical frequency combs, Brillouin lasers, atomic and ion transition trapping, cooling and locking, laser stabilization, phase lock loops, beam steering gratings, optical tweezers, and cryogenic applications, can benefit from integrated, low power, active modulation. Yet it has remained a challenge to transition these modulators to semiconductor waveguides (e.g. silicon nitride waveguides) while maintaining the ultra-low optical loss in a CMOS-compatible, wafer-scale process. Therefore, integrated control modulators that maintain the desirable properties of the semiconductor waveguides, as well as low-power consumption, are needed.

There have been efforts to realize tuning and modulation in ultra-low loss semiconductor photonics. For example, silicon nitride has a high third-order Kerr nonlinearity which is suitable for generating octave-spanning frequency comb, however, due to its centrosymmetric crystal structure, silicon nitride has a small second-order Pockels effect with a maximum electro-optic (EO) coefficient of about 8.31±5.6 fm/V and cannot make use of free-carrier modulation like silicon. Conventional thermal tuning approaches support bandwidths up to about 10 KHz with about 40 mW silicon nitride tuners. Integration of nonlinear materials and silicon nitride waveguides may introduce second-order nonlinearities for EO modulation, for example lithium niobate, ferroelectrics, and zinc oxide. These methods offer modulation bandwidths greater than about 1 GHZ, however, they suffer from large optical losses, increased fabrication complexity, high power consumption and can have limited material optical wavelength range. The stress-optic effect may offer a broad optical bandwidth, moderate electrical bandwidth, and low power consumption. Stress-optic actuated silicon nitride waveguides have been demonstrated using piezoelectric materials such as aluminum nitride (AlN) and PZT. AlN actuation utilizes acoustic resonant enhancement due to its relatively small piezoelectric coefficient (AlN: e_{31,f}=1.02 C/m², PZT: e_{31,f}=−18.3 C/m²) and tuning efficiency which is an order of magnitude weaker than that of PZT. The under-etched PZT approach may result in high loss, low Q, limited modulation bandwidth (less than about 1 MHZ), but is difficult to make compatible with planar wafer-scale integration. Progress has been made with planar processed PZT actuators including a Mach-Zehnder interferometer (MZI) phase modulator with a modulation bandwidth of 629 kHz and high optical loss. Additional benefits can be realized by combining these material platforms with stress-optic actuation and their optical and electrical properties, such as silicon nitride and lithium niobate, and combining properties of silicon nitride waveguide stress-optic actuation with silicon photonics.

Some examples include ultra-low power stress optic actuators in photonic integrated circuits using silicon nitride waveguides. However, these solutions include stress-optic modulators that can operate in the IR wavelength ranges, but may not be ideal for the visible light wavelength ranges. In addition, the actuators are positioned on top of the ring resonators without any offset distance and can adversely affect the optical loss. Additionally, placing these actuators directly overlapping the ring resonators requires a material, such as aluminum nitride (AlN) that includes resonant modulation such that the actuator is positioned in proximity to the waveguide core material in order to modulate its index and this modulation is done at a particular resonant frequency, making DC biasing not possible and making broadband modulation require complex, no-optimal, modulation structures, and making design across the visible to mid-IR impractical.

Some further examples include low noise hybrid photonic integrated lasers with silicon nitride microresonators combined with aluminum nitride or lead zirconium titanate based stress-optic actuators. However, the modulator may only work with AC biasing when the actuators are positioned on top of the ring resonators without offset.

Some further examples include electrically tunable optical resonator on a chip for fast tunable integrated lasers. However, the modulator operates under AC signals. These solutions may further include using multiple actuators such as a dummy actuator or an auxiliary actuator for tuning. In addition, the actuator may cover at least 90% of the resonator plane.

Many embodiments of this disclosure include compact, low power, low loss waveguide structures on CMOS wafer-scale manufacturable photonic waveguides. One example of these waveguide structures is modulators. The modulators in accordance with several embodiments have advantages including (but not limited to): 1) lower loss, 2) operating broadband, 3) utilizing DC and/or AC as input signals, 4) only one actuator to achieve broadband tuning; 5) accommodate with light from UV wavelength range to visible wavelength range to mid-IR wavelength range. Table 1 below lists the comparison of properties of the stress optic modulator in accordance with embodiments and other work.

| | | 3 dB BW | Loss | VπLα | Tuning | | ER | | | |
|---|---|---|---|---|---|---|---|---|---|---|
| Modulator | Actuation | (MHz) | (dB/cm) | (V · dB) | (pm/V) | Q | (dB) | Power | | Ref. |
| SiN/MZI | PZT/SO | 0.629 | NA | NA | NA | NA | NA | 25 | | N. Hosseini |
| SiN/MZI | PZT/SO | 1.18 | <0.1 | 1.6 | NA | NA | NA | <1 | μW | A. S. Everhardt |
| SiN/Ring | PZT/SO | <1 | 0.3 | 1.1 | 25.75 | Q_{L} = 86K | 15 | 160 | nW | W. JIN |
| SiN/Ring | AIN/SO | 91.71 | 0.02 | NA | 0.12 | Qᵢₙ = 15M | NA | 300 | nW | J. Liu* |
| SiN/Ring | PZT/SO | NA | 0.01 | NA | 4.16 | Qᵢₙ = 15M | NA | NA | | Lihachev |
| SiN/Ring | PZT/SO | DC-15 (3 | 0.03 | 1.3 | 1.3 | Q_{L} = 3.6M | 14 | 20 | nW | Example |

| | | |
|---|---|---|
| dB)/DC-25 | Qᵢₙ = 7.1M | embodiment |
| (6 dB) | | |

Many embodiments implement integration of a piezo-electric material including (but not limited to) lead zirconate titanate (PZT) actuated micro-ring modulation in a fully-planar, wafer-scale silicon nitride waveguide. As can be readily appreciated, any of a variety of a stress tuner material can be utilized appropriate to the requirements of specific applications in accordance with various embodiments of the invention. The modulator in accordance with several embodiments can maintain low optical loss, for example about 0.03 dB/m at 1550 nm, 0.3 dB/m at 780 nm, 0.6 dB/m at 674 nm. In some embodiments, the modulators can achieve broadband modulation including (but not limited to) DC—about 15 MHz 3-dB and DC—about 25 MHz 6-dB. In certain embodiments, the modulators have a low power consumption of about 10 nW to 20 nW. Several embodiments provide that the modulator has desirable characteristics including (but not limited to) high extinction ratio and low loss that remain relatively constant over the whole tuning and modulation range and over broad ranges of wavelength, for example the visible, such that the basic waveguide design and fabrication process remain relatively the same. In many embodiments, the PZT actuators can use various input signals including (but not limited to) low frequency signals, DC signals, high-frequency radio frequency (RF) signals, and AC signals, to initiate the mechanical actuation that then causes the stress-optic response. In a number of embodiments, it is preferred that the stress-optic actuator is designed to apply a DC to AC response that is flat and not require resonant opto-mechanical structures, design, or modulation. In a number of embodiments, the PZT modulators can use one circular resonator modulator to achieve broadband modulation, e.g., flat frequency response from low (DC to 100 s of MHz) instead of using multiple resonators and resonant optomechanical and stress optic approaches. These embodiments have advantages over such resonant modulation actuators and actuators that are complex and not compatible with CMOS type integration such as etched or released structures. Examples of circular resonators include (but are not limited to): loop resonators, coil resonators, ring resonators, and racetrack resonators. In some embodiments, multiple actuators such as a damping actuator, an auxiliary actuator, and/or a dummy actuator may be added but not necessary to achieve the broadband. In preferred embodiments it is not desirable to use auxiliary dummy or damping actuators in order to achieve DC to AC modulation and it is not desirable to use resonant stress-optic modulation or under-etched structures.

Optical modulators may be an important part of many optical applications including (but not limited to) modulation-based control and locking of lasers, filters, optical frequency combs, and other photonic components. Such modulators have many applications that span from visible wavelength to infrared (IR) wavelength, including (but not limited to) optical fiber communications, optical metrology and sensing, atomic clocks and timekeeping, atomic sensors, quantum computing and sensing, quantum communications, optical navigation, precision spectroscopy and microwave photonics. Conventional modulators that are used to realize these control functions include high-power bulk-optic components (such as acousto-optic (AOM) and electrooptic (EOM)) for tuning, sideband modulation, and phase and frequency shifting, while providing low optical insertion loss and operation from DC to about 10 s and 100 s of MHz. Very low loss photonic integration is needed to make these systems compact, and reduce their size, weight and cost of related applications as well as improve their scalability and reliability. Photonic integration such as silicon nitride (Si₃N₄), tantalum pentoxide (tantala) and amorphous alumina oxide (alumina) offer very low losses from the UV through the visible and into the infrared (IR) wavelengths as well as manufacturability at the wafer-scale. However, in order to realize the many applications at the chip-scale, the modulation control functions need to be implemented in a low loss, wafer-scale CMOS-compatible photonic integration. In particular, the silicon nitride waveguides can be used to realize extremely low waveguide losses across the visible to infrared wavelengths and components including (but not limited to) high performance lasers, filters, resonators, stabilization cavities, and optical frequency combs. To support other wavelengths, for example the deep blue and UV, Tantala (Ta₂O₅) or alumina waveguide (Al₂O₃) can be utilized.

Many embodiments integrate compact, low power, low loss modulators on complementary metal oxide semiconductor (CMOS) wafer-scale manufacturable photonic waveguides including (but not limited to) the silicon nitride waveguides that have a stress-optic coefficient in the waveguide core which changes the waveguide index of refraction in response to the appropriate stress-optic actuation. Many embodiments provide the required modulation while maintaining the very low loss waveguide design and properties by ensuring that the stress-optic actuators do not overlap substantially with the optical waveguide mode. Many embodiments provide the required low loss and planar photonic integrated geometry by utilizing wafer-scale processing waveguide designs without requiring releasing or under-etched structures. Examples of photonic waveguide include (but are not limited to) silicon nitride, tantalum pentoxide, amorphous aluminum oxide, atomic layer deposition (ALD) aluminum oxide, and aluminum nitride. As can be readily appreciated, any of a variety of a photonic waveguide can be utilized appropriate to the requirements of specific applications in accordance with various embodiments of the invention. The ultra-low loss modulators in accordance with several embodiments reduce cost, size and complexity of conventional bulk-optic modulation. The compact modulators in accordance with a number of embodiments can be further integrated into and with components including (but not limited to) filters, lasers, isolators, circulators, external cavity tunable lasers (ECTL), optical frequency combs, external distributed Bragg reflector lasers (EDBRs), and semiconductor lasers and gain chips, for systems-on-chip solutions.

In some embodiments, laser stabilization can use the modulator in a Pound-Drever Hall (PDH) lock loop configuration. The integration of the modulator in a PDH lock loop in accordance with several embodiments that can further reduce laser frequency noise from the very low frequencies, to the mid-frequencies, to higher frequencies (e.g., >100 kHz). In certain embodiments, the modulator can be used as a laser carrier tracking filter. Various embodiments combine the PDH lock loop and the laser carrier tracking filter for laser stabilization. The PZT modulator design can be extended to the visible in the ultra-low loss silicon nitride waveguide with minor waveguide design changes in accordance with many embodiments. Several embodiments provide that advantages of the modulator include (but are not limited to) the modulation of the waveguide index can be performed with the stress-optic actuator located away from the optical mode so as not to affect the loss. In many embodiments, the actuator is offset from the center of the waveguide. This advantage can make the modulator applicable to designs that function at a broad range of wavelengths, for silicon nitride waveguides, from the visible range (wavelength from about 405 nm to about 700 nm) to the IR range (wavelength from about 780 nm to about 2350 nm) with minor waveguide structural changes using the same modulator design and fabrication process. Examples of structural changes include (but are not limited to) silicon nitride thickness and/or silicon nitride width. For wavelengths outside this range, many embodiments implement materials that are transparent to the far-UV, UV and near-UV range and that also have a stress optic effect. Examples of UV transparent materials include (but are not limited to) GaN and alumina and tantala. Some embodiments optimize the modulation out to about 1 GHz and above. Using PZT in the modulator has the ability to control DC and low frequencies as well as AC and higher frequencies without the disadvantages and complexity of resonant type modulators. Many embodiments implement various types of stress optic materials in the modulator where the optical loss is minimally affected and the DC to higher frequency modulation is possible. As can be readily appreciated, any of a variety of a stress optic material can be utilized in the modulator appropriate to the requirements of specific applications in accordance with various embodiments of the invention. This integration of PZT modulation in the ultra-low loss silicon nitride waveguide in accordance with many embodiments enables modulator control functions in a wide range of visible to IR applications including (but not limited to) atomic and molecular transition locking for cooling, trapping and probing, controllable optical frequency combs, low-power external cavity tunable lasers, quantum computers, sensors and communications, atomic clocks, and tunable ultra-low linewidth lasers and ultra-low phase noise microwave synthesizers.

Systems and methods for implementing the low-loss modulators in accordance with various embodiments of the invention are discussed in further detail in the attached appendix.

### Stress Optic Modulator

Many embodiments implement low-power photonic integrated piezoelectric actuated stress-optic microresonator modulator for optical control functions. The modulators in accordance with several embodiments are CMOS manufacturing processes. In several embodiments, the modulators implement ultra-low loss silicon nitride waveguides with piezoelectric materials including (but not limited to) PZT and AlN and can include semiconductors or other materials with stress optic effects such as gallium nitride (GaN) and bismuth tin oxide (BTO). As can be readily appreciated, any of a variety of a piezoelectric material can be utilized appropriate to the requirements of specific applications in accordance with various embodiments of the invention. Examples of photonic waveguides include (but are not limited to) silicon nitride, tantalum pentoxide, amorphous and ALD alumina oxide, and aluminum nitride. Semiconductor waveguides can also be employed using the appropriate bandgap semiconductor to guide the light, such as GaN, GaAs, AlGaAs, InGaAs, InAlGaAs, InP, etc. As can be readily appreciated, any of a variety of a photonic waveguide and/or a waveguide can be utilized appropriate to the requirements of specific applications in accordance with various embodiments of the invention. In many embodiments, the actuator is offset from the center of the waveguide. Certain embodiments implement fully planar structures of the modulator. In some embodiments, the silicon nitride waveguide layers are fabricated in CMOS compatible processes and can withstand temperatures less than or equal to about 1200° C. The PZT can be deposited at a lower temperature on the silicon nitride wafers after the CMOS process such that it is compatible with the ultra-low loss silicon nitride process. In addition, since the modulation is based on stress-optic induced changes in the silicon nitride waveguide core, and the optical mode does not overlap with the actuators, the modulator design can be adaptable to wavelengths from visible light range to infrared range and maintain the low waveguide loss properties. Several embodiments can change the modulator geometries including (but not limited to) thickness and/or width to transfer the modulator to the visible range. The ability to modify the modulator geometry for various wavelength makes the modulator applicable for various AMO applications including (but not limited to) strontium transitions in the about 461 nm to about 802 nm wavelength range, rubidium transitions in the about 780 nm range, other atomic and molecular species with transitions across the nitride transparency window (from about 405 nm to about 2350 nm). Other applications in the visible to IR can include biological, medical, and sensing such as LIDAR. The ultra-low loss waveguide modulators in accordance with various embodiments may enable chip-level control to be integrated with other ultra-low loss silicon nitride components for a wide range of visible to IR applications, including atomic and molecular quantum sensing, computing and communication, controllable optical frequency combs, low-power stabilized lasers, atomic clocks, and ultra-low phase noise microwave synthesizers.

In many embodiments, the stress-optic modulator comprises a semiconductor circular resonator and an actuator. The semiconductor circular resonator in accordance with some embodiments can be made with a semiconducting material that is suitable as a photonic waveguide. The waveguide can guide light and contain at least a region of increased refractive index, compared with the surrounding medium (also known as cladding). Examples of the semiconductor waveguide materials include (but are not limited to) silicon nitride, tantalum pentoxide, amorphous alumina oxide, and aluminum nitride. In a number of embodiments, the circular resonator can have a shape of a loop resonator, a ring resonator, a racetrack resonator, or any resonator with a closed-loop circuit. In several embodiments, the actuator can be made with a piezoelectric material including (but not limited to) PZT or aluminum nitride. Examples of cladding materials include (but are not limited to) silicon oxide. In some embodiments, the actuator can be positioned on top of the ring resonator concentrically. In a number of embodiments, the actuator can be positioned on top of the ring resonator with an offset distance from the center of the ring resonator such that the optical modes of the actuator and the resonator are not overlapped. The offset distance in accordance with certain embodiments enable the modulator to achieve better performance without optical loss. In certain embodiments, cladding layers can be deposited surrounding the ring resonator. The thickness of the cladding layers in between the ring resonator and the actuator can be modified to achieve optimal performances of the modulator in accordance with many embodiments. Certain embodiments provide that the optimal thickness of the cladding layer between the ring resonator and the actuator depends on the piezoelectric material used in the modulator. In many embodiments, metal electrodes can be deposited on the piezoelectric actuators to establish electrical contacts. DC and/or AC power supplies can be used as power source to operate the piezoelectric actuators in accordance with several embodiments. Static tuning of the actuator can shift the ring resonance as a function of applied bias voltage. Strain can be induced through the piezoelectric effect which can change the waveguide refractive index. The stress-optic modulator including the ring resonator and the actuator can be fabricated using CMOS-compatible processes in accordance with a number of embodiments. The ring resonator may be a circular waveguide or a ring waveguide.

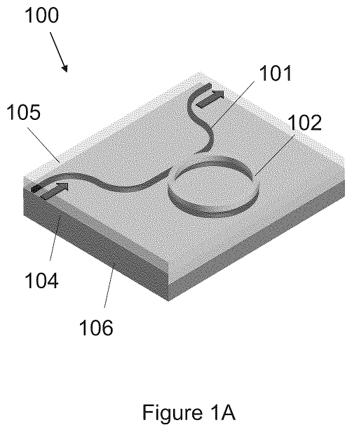

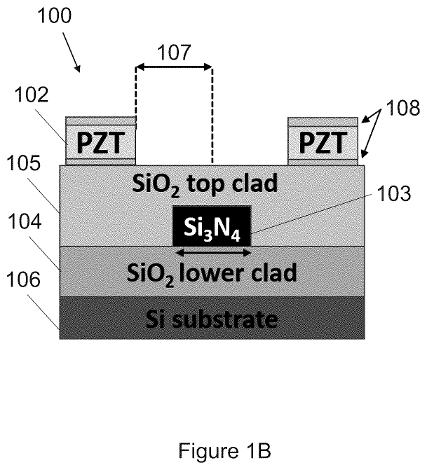

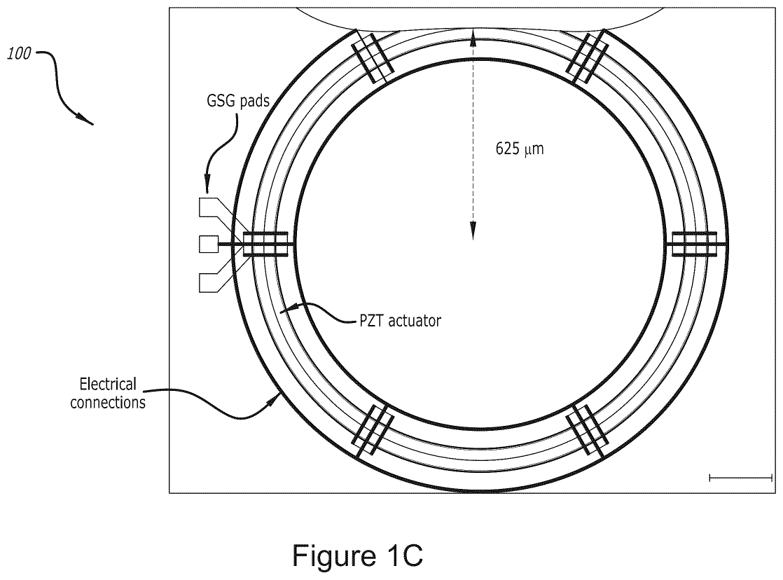

FIGS. 1A through 1C illustrate a stress-optic modulator configuration in accordance with an embodiment of the invention. FIG. 1A illustrates a top down view of the modulator. FIG. 1B illustrates a cross section of the modulator in FIG. 1A. FIG. 1C illustrates a top-down image of the fabricated device shown in FIG. 1A. The stress-optic modulator 100 includes a silicon nitride ring resonator 101 and a PZT actuator 102. The silicon nitride ring resonator can be monolithically integrated with PZT actuator as shown in FIG. 1A. The ring resonator 101 has a radius of about 625 μm and can be fabricated using the silicon nitride ultra-low loss CMOS-compatible waveguide process. As can be readily appreciated, the resonator can have any of a variety of a circular shape as appropriate to the requirements of specific applications in accordance with various embodiments of the invention. As can be readily appreciated, the circular resonator can have any of a variety of a diameter including (but not limited to) greater than 625 μm or less than 625 μm as appropriate to the requirements of specific applications in accordance with various embodiments of the invention. The ring resonator can include a Si₃N₄ waveguide core 103. The Si₃N₄ waveguide core 103 can have a thickness of about 175 nm, and a width of about 2.2 μm. The Si₃N₄ core can be deposited using chemical vapor deposition processes including (but not limited to) low pressure chemical vapor deposition (LPCVD). The Si₃N₄ waveguide core can be sandwiched between a lower silicon oxide cladding layer 104 and a top silicon oxide cladding layer 105. The lower silicon oxide cladding layer 104 can have thickness of about 15 μm and can be thermally grown on a silicon substrate 106. The top silicon oxide cladding layer 105 can have a thickness of about 6 μm, and can be deposited using chemical vapor deposition processes including (but not limited to) plasma enhanced chemical vapor deposition (PECVD) using tetraethylorthosilicate (TEOS). In some embodiments, chemical-mechanical polishing (CMP) can be performed on top of the upper silicon oxide layer 105 to planarize the surface. A PZT layer 102 can be deposited on the waveguide core 103. The PZT layer 102 can have a thickness of about 500 nm. As can be readily appreciated, the PZT layer can have any of a variety of a thickness including (but not limited to) greater than about 500 nm or less than about 500 nm as appropriate to the requirements of specific applications in accordance with various embodiments of the invention. The PZT layer 102 can have upper and lower platinum (Pt) electrodes 108 to establish electrical contact. An adhesion layer (not shown) including (but not limited to) TiO₂ adhesion layer can be deposited between the electrode 108 and the top silicon oxide cladding layer 105. In several embodiments, the PZT layer 102 can be deposited and patterned laterally and/or vertically offset from the waveguide core 103 by a distance 107 with respect to its center. The PZT actuator dimensions and waveguide-offset are designed to achieve a large lateral strain effect across the nitride core while minimizing overlap with the optical mode, and therefore minimize optical losses. In certain embodiments, the optical modes of the actuator and the resonator are not overlapped. The off-set distance 107 of the PZT layer can be from about 2 μm to about 5 μm; or less than about 2 μm; or greater than about 5 μm. A 2 μm off-set distance is shown in FIG. 1B. In FIG. 1C, it is seen that the PZT actuators form concentric rings. The PZT actuators are below electrodes. These electrodes may be utilized to control the actuators.

The off-set distance 107 is the distance from the inner edge of the PZT layer 102 to the center of the waveguide core 103. The off-set distance 107 may depend on the device design and the wavelength. An off-set distance 107 of 2 μm to 5 μm may be included for a 1550 nm wavelength waveguide. In some embodiments, for a waveguide design with 2 μm width×20 nm thick at 780 nm wavelength waveguide, the optimized offset is 1-2 μm which may optimize between low loss and strong index change. At 780 nm wavelength, the cladding may be 4 μm thick.

As illustrated, the off-set distance of the inner PZT layer 102 may be the same as the off-set distance of the outer PZT layer 102. In some embodiments, The off-set distance for the inner PZT layer 102 can be different than the off-set distance for the outer PZT layer 102.

While these waveguide-offset piezo-electric actuators have been described in the context of ring modulators, it is understood that this design may be applicable to semiconductor waveguides in general such as a straight waveguide or waveguides of arbitrary routing patterns, for example serpentines. The piezo-electric actuators may change the phase of light propagating through the waveguide based on the voltage applied to the piezo-electric actuators.

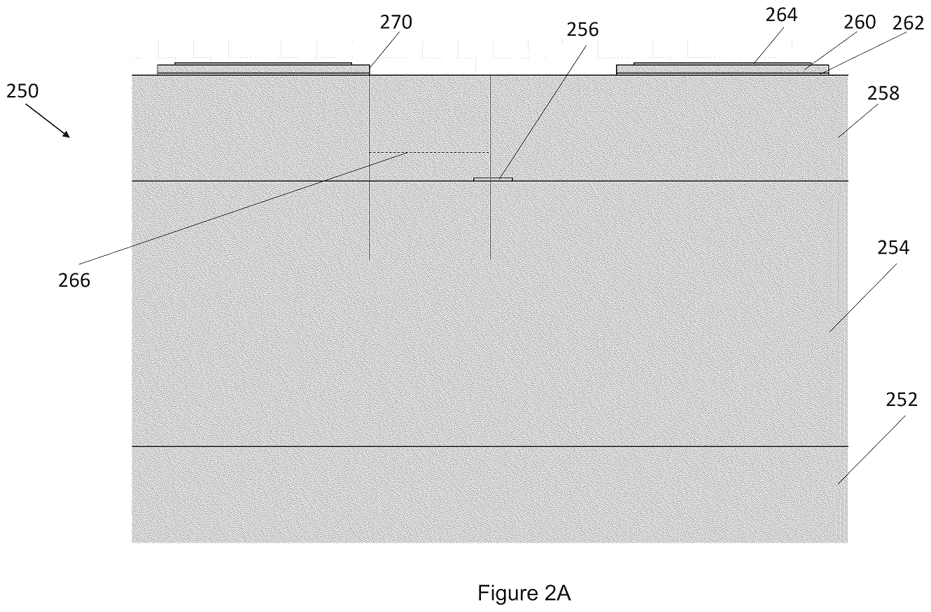

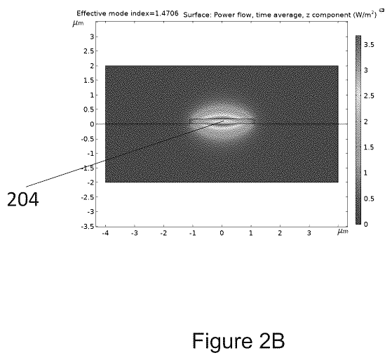

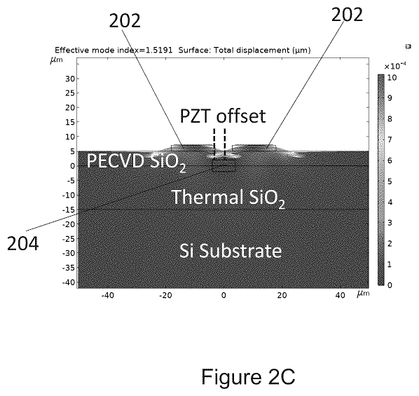

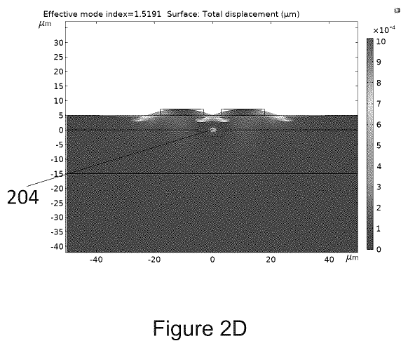

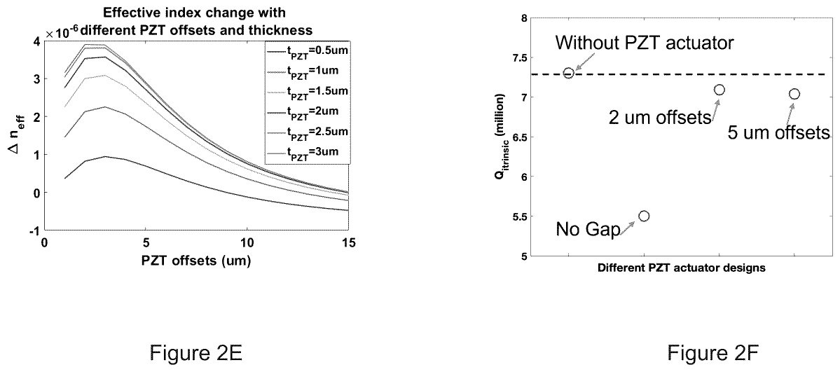

FIG. 2A illustrates an example cross sectional schematic for a stress-optic modulator 250 in accordance with an embodiment of the invention. The stress-optic modulator 250 includes a substrate 252. The substrate 252 may be a Si substrate of thickness of 1000 μm. An insulator layer 254 is positioned on the substrate 252. The insulator layer 254 may be a thermally deposited SiO₂ layer with thickness of 15 μm and a refractive index of 1.45. A waveguide 256 may be positioned on the insulator layer 254. The waveguide 256 may be Si₃N₄. The waveguide 256 may have a refractive index of 1.95. The waveguide 256 may have a thickness of 175 nm and a width of 2.2 μm. The waveguide 256 may be embedded in a cladding layer 258. The cladding layer 258 may be SiO₂. The cladding layer 258 may have a thickness of 6 μm. A piezoelectric modulator may be positioned on the cladding layer 258 in an offset position from the waveguide 256. The piezoelectric modulator may surround the waveguide 256 in an offset position to not cover the waveguide 256. The edge 270 of the piezoelectric modulator may be offset from the center of the waveguide 256 by a distance 266. The distance 266 may be 2 μm. The piezoelectric modulator may include a piezoelectric material 260 positioned between a first electrode 262 and a second electrode 264. The first electrode 262 and the second electrode 264 may apply a voltage across the piezoelectric material 260 which may deform the piezoelectric material 260 to modulate various properties of the waveguide 256.

As illustrated, the piezoelectric actuator may be offset from the center of the ring resonator. The offset distance from the center of the ring resonator can be modified to achieve optimal modulator performance with ultra-low loss in accordance with some embodiments. In many embodiments, the offset distance can maximize the stress-optic effect and minimize overlap with the optical mode in order to preserve the low optical loss. The PZT design is offset from the waveguide core and optical mode, resulting in a resonator Q and modulation extinction ratio that are relatively constant over a 4 GHz tuning range. FIG. 2B illustrates an optical mode simulation of a PZT actuator model in accordance with an embodiment of the invention. The optical mode simulation shows optical energy of the actuator. The simulation can be carried out using COMSOL Multiphysics to simulate the stress distribution, total displacement and effective mode index change due to the stress-optic effect. FIG. 2C illustrates stress distribution of a PZT actuator model in accordance with an embodiment of the invention. The stress distribution can be indicated by the total displacement plot. The PZT actuator model has an offset distance of about 2 μm. FIG. 2D illustrates a PZT actuator model to simulate the offset distance in accordance with an embodiment of the invention. In FIGS. 2B-2D, the PZT actuator 202 (including PZT film and platinum electrodes) is placed at a lateral (horizontal) offset with respect to the optical waveguide center of the optical waveguide 204 and on top of the upper cladding. FIG. 2D is a combination of FIG. 2B and FIG. 2C, and it shows the optical mode is not affected much by the PZT actuator. Thus, the PZT actuator can create modulation of the waveguide functionality without a decrease of performance.

FIG. 2E illustrates the effective index change as a function of PZT offset distance and PZT thickness in accordance with an embodiment. The effective index changes as different PZT offset distances (x axis) and thickness (lines). As shown in FIG. 2E, an offset distance of about 2 μm results in the largest index change among all thickness tested. FIG. 2F illustrates different quality (Q) factor and loss as a function of PZT offset distance in accordance with an embodiment. Fabricated resonators with different PZT offsets are tested for Q and loss. When the PZT actuator is located directly above the waveguide, the Q and the loss are reduced by approximately 20% compared to without the PZT actuator. With the PZT actuator laterally offset by 2 μm from the waveguide and fabricated on top of the upper oxide cladding, the reduction in loss and Q are under a few tenths of a dB.

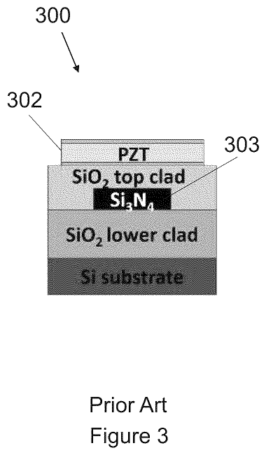

In many embodiments, the offset distance between the actuator and the resonator can be important to minimize the optical loss. Various previous modulators have the actuator and the resonator overlap with each other such that the optical modes are overlapping. FIG. 3 illustrates a cross section of a conventional stress-optic modulator configuration. The stress-optic modulator 300 includes a silicon nitride ring resonator and a PZT actuator. As can be seen, the PZT layer 302 is deposited and patterned concentrically with the waveguide core 303. The actuator overlaps with the resonator and the optical fields also overlap. However, as discussed above, the quality factor increases based on the offset of the PZT actuator from the resonator. Loss was observed to decreased in the presence of the offset. Also, based on FIG. 2E, with certain offset, the index change induced to the optical waveguide (e.g. stress-optic effect) may be the largest. Thus, an optical offset exists based on certain designs of optical waveguides.

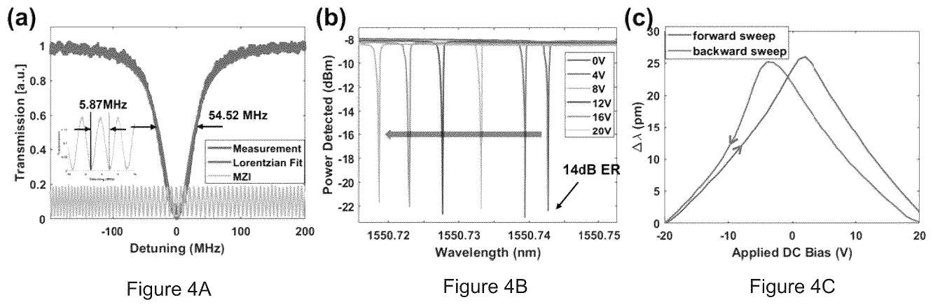

Several embodiments provide the performance of the stress-optic modulators. FIG. 4A illustrates the Q measurement of the resonator in accordance with an embodiment of the invention. The full-width-at-half-maximum (FWHM) of the modulator resonance is measured to be about 54.52 MHz at 1550 nm using a radio frequency (RF) calibrated unbalanced MZI with 5.87 MHz free-spectral-range (FSR) as a frequency ruler. The measurement yields about 7.1 million intrinsic Q, about 3.6 million loaded Q, and a corresponding 0.03 dB/cm waveguide loss.

FIG. 4B illustrates the optical transmission spectrum of the static tuning of the modulator in accordance with an embodiment of the invention. Static tuning of the PZT actuator can shift the ring resonance as a function of applied bias voltage. The electric field can be applied to the PZT actuator electrodes using a DC probe and strain can be induced through the piezoelectric effect which changes the waveguide refractive index. The resonance has about 14 dB extinction ratio (ER) across the 4 GHz tuning range, as the applied voltage is varied from about 0 V to about 20 V.

FIG. 4C illustrates the PZT hysteresis measured with reverse biasing in accordance with an embodiment of the invention. Nonlinearity and hysteresis can be observed in static tuning by sweeping the DC bias voltage in both forward (from about −20 V to about 20 V) and backward (from about 20 V to about −20 V) direction. The hysteresis may be due to the ferroelectric nature of PZT. The average tuning coefficient is about −1.3 pm/V or about −162 MHz/V. The half-wave voltage-length product VπLα of the modulator is about 43 V·cm and VπLα when taking the waveguide loss into account is about 1.3 V·dB. The electrical power consumption is about 20 nW at about 20 V bias voltage with about 100 fA measurement resolution.

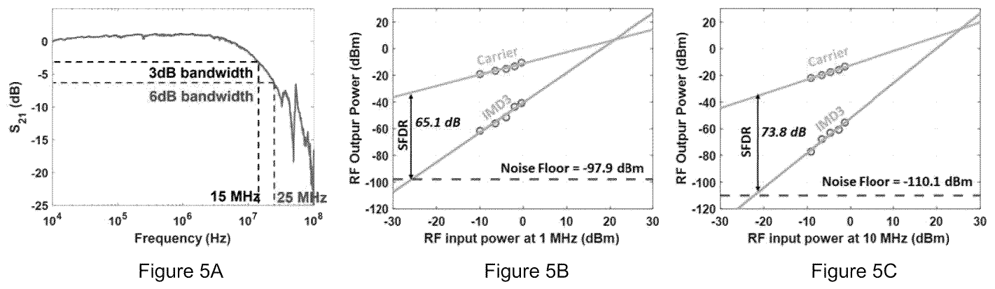

FIG. 5A illustrates the frequency response in accordance with an embodiment of the invention. The small-signal electrical-to-optical modulation response can be measured by modulating a semiconductor diode laser tuned to the FWHM point of the resonance, a calibrated fast photodetector (bandwidth about 1.2 GHz) and a vector network analyzer. As shown in FIG. 5A, the 3-dB and 6-dB modulation bandwidths are about 15 MHz and about 25 MHz respectively. Using an effective bandwidth model for ring resonator modulators operating off-resonance, the actuator RC bandwidth can be about 120 MHz, and the effective optical bandwidth of the resonator can be about 80 MHz. Based on the 3-dB measurement shown in FIG. 5A, the optomechanical PZT response can be approximately 15 MHz. The modulation bandwidth can be further improved by optimizing the optomechanical design and the tuning strength can be improved using a thicker PZT film as well as a thinner oxide cladding. Improvements can be made to extend the bandwidth to 25 MHz, 50 MHz, 100 MHZ, 100 s MHz and GHz.

The modulator linearity for applications such as PDH locking can be measured using the IMD3 SFDR. The SFDR is defined as the signal level at which the noise floor and power of the third order distortion tone are equal. The two-tone test is performed by applying two closely placed RF signals to the modulator and measuring the intermodulation components at the optical output using an electrical spectrum analyzer (ESA). FIGS. 5B and 5C illustrate RF output power of the fundamental and third order intermodulation distortion (IMD3) component as a function of RF input power of the ring modulator at about 1 MHz and about 10 MHz respectively in accordance with an embodiment. The measured noise floor is about −97.9 dBm/Hz at about 1 MHz and −110.1 dBm/Hz at about 10 MHz. IMD3 SFDR values of about 65.1 dB Hz^{2/3} and about 73.8 dB Hz^{2/3} are measured at 1 MHz and 10 MHz, respectively.

Systems and methods for using the stress-optic modulator as a double sideband (DSB) modulator in a laser frequency stabilization PDH lock loop, and as a laser frequency tracking filter are described further below.

Many embodiments of the invention include other waveguide and photonic integrated structures including phase tuning and phase modulation of a straight waveguide, phase tuning and modulation of a spiral or other waveguide shape such as a serpentine structure, or phase tuning and modulation of a coil-resonator structure. Other arbitrary waveguide shapes that can be integrated as waveguides can be tuned and modulated using the disclosed stress-optic modulator including s-bends, u-shapes and other shapes. The stress optic actuated waveguides and ring resonators can be further integrated into structures such as interferometers, where the straight, spiral, and ring- or coil-resonator structures, or other shaped waveguide structures are used in one or both arms of an interferometer including a Mach-Zehnder or Michaelson interferometer, or in the arm of a Sagnac interferometer, or in other interferometer structures. Such actuation in interferometer structures may allow tuning and modulation and scanning. The invention can be used to tune and modulate one or more arms in a multi-arm interferometer design such as arrayed-waveguide gratings. As described above, the stress-optic modulator may include offset piezoelectric actuators which are offset from the waveguide.

### Stress Optic Modulator for Ultra-Low Loss Planar Photonic Integration

Many embodiments implement control applications with the stress-optic modulators. In some embodiments, the modulator can be used for PDH stabilization of a laser to an optical reference cavity. In certain embodiments, the modulator can be used for laser filter tracking. The compatibility of the planar modulator with other silicon nitride devices including (but not limited to) filters, Brillouin lasers, stabilization cavities, can lead to more functions on-chip. Tracking circuits can be useful when aligning modulators to wavelength-division multiplexing (WDM) transmitter channels, for filtering a channel or aligning add/drop filters for a WDM transmission system or network. Applications that can benefit from photonic integration with the planar stress-optic modulator include (but are not limited to) frequency comb control and tunable stimulated Brillouin scattering (SBS).

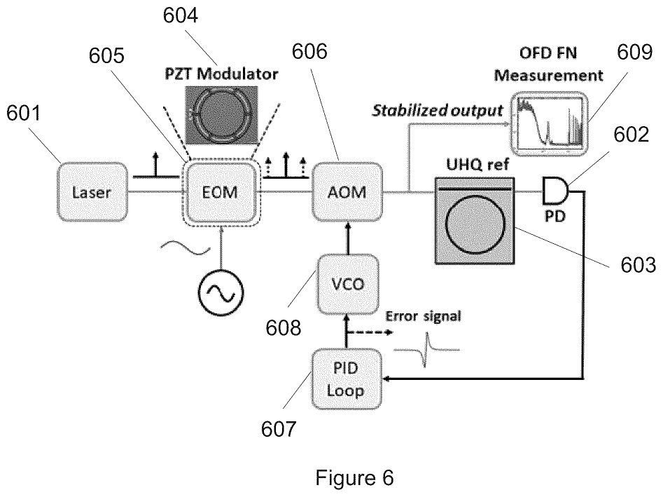

FIG. 6 illustrates a PDH locking setup in accordance with an embodiment of the invention. A semiconductor laser 601 is PDH locked to an ultra-high Q (UHQ) reference cavity 603 using the PZT modulator 604 as a double sideband (DSB) modulator. The PZT modulator is used in place of an electro-optic modulator (EOM) 605 that is typically used in PDH stabilization, to generate double sidebands on the laser carrier. An acousto-optic modulator (AOM) 606 is used to frequency shift the DSB modulated carrier and lock it to a reference cavity resonance 603. The reference cavity 603 is an integrated silicon nitride bus-coupled resonator with an ultra-high Q of about 10⁸ and large mode volume of about 2.9×10⁶ μm³. The narrow resonance provide by the high Q is utilized to suppress the laser frequency noise fluctuations and the large mode volume is chosen to reduce the thermo-refractive noise (TRN) floor. The double sideband modulated carrier can be frequency shifted by an AOM and locked to the quadrature point of an UHQ integrated reference resonator (through a photodetector 602) using a proportional-integral-derivative (PID) control loop 607 that drive a voltage-controlled oscillator (VCO) 608 AOM frequency shift control signal. The resulting stabilized frequency noise can be measured using an unbalanced fiber MZI optical frequency discriminator (OFD) 609.

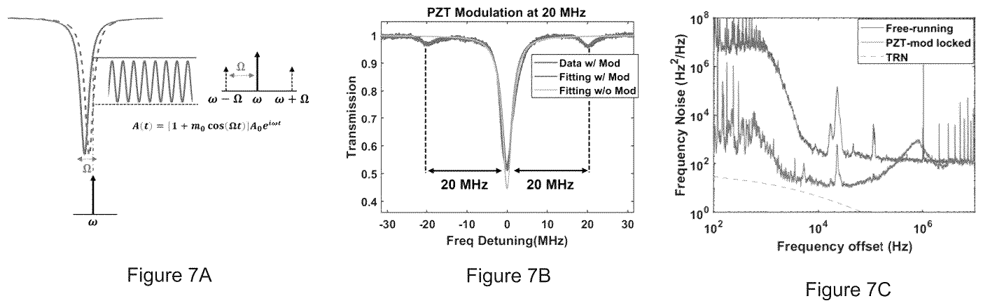

FIGS. 7A through 7C illustrate the performance of the modulator in the PDH locking application in accordance with an embodiment. FIG. 7A illustrates the DSB modulated carrier. The modulation depth of the DSB modulated carrier can be an important consideration for laser noise stabilization. In FIG. 7A, a 20 MHz, 8 V peak-to-peak sinusoidal voltage is applied to the PZT actuator. Amplitude modulation produces a modulation depth that can be approximated by:

$$A ( t ) = [ 1 + {m}_{0} cos ( Ω t ) ] {A}_{0} {e}^{i ω t} = {A}_{0} {e}^{i ω t} + \frac{{m}_{0} {A}_{0}}{2} {e}^{i ( ω + Ω ) t} + \frac{{m}_{0} {A}_{0}}{2} {e}^{i ( ω - Ω ) t} \qquad ( 1 )$$

FIG. 7B illustrates measured DSB spectrum of the laser signal with and without the PZT DSB modulation. The sideband modulation depth at ω±Ω is calculated to be m₀=0.48 by fitting Eqn. (1) to the measured response with the sideband-to-carrier power ratio

$$\frac{{m}_{0}^{2}}{2} = 12 \% .$$

The laser frequency noise is measured using the self-delayed homodyne laser frequency noise method with an unbalanced fiber MZI optical frequency discriminator (OFD) with an FSR of about 1.03 MHz. The power spectral density of the frequency noise as a function of frequency offset from carrier is shown in FIG. 7C. The stabilized laser frequency noise (red curve) is reduced by four orders of magnitude (about 40 dB) compared to the unstabilized laser over the frequency range 100 Hz to 1 kHz and reduced by two orders of magnitude (about 20 dB) at about 10 KHz frequency offset. The laser stabilization locking circuits has a bandwidth of about 1 MHz where the servo bump can be seen in the stabilized frequency noise measurement. The TRN floor is calculated for the silicon nitride high Q resonator as shown in the green dashed curve in FIG. 7C. The stabilized laser is able to achieve close to the TRN limit for this cavity over the frequency range of about 1 kHz to 10 KHz. The demonstrated PZT-actuated ring modulator can be an ideal on-chip and low power solution to the bulk EOM component and provide enough bandwidth in a PDH locking circuit for laser stabilization.

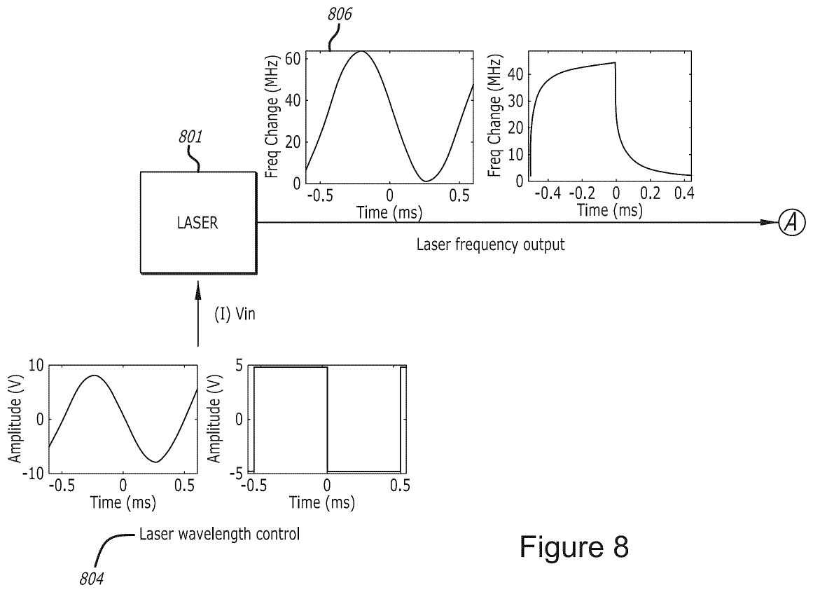

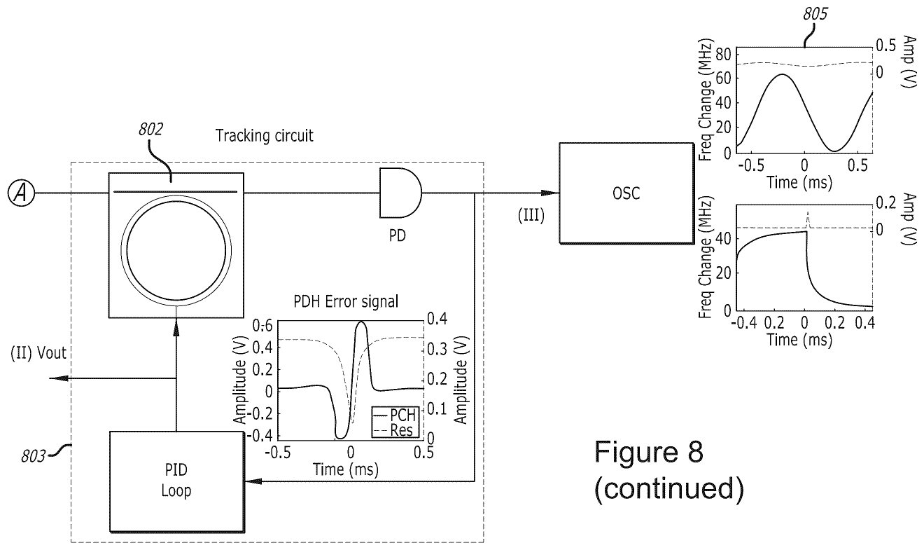

In several embodiments, the stress-optic PZT modulators can be used for automated laser carrier tracking filter. Laser carrier tracking can be important for monitoring and stabilizing wavelength changes to minimize the wavelength drift and spectral misalignments which cause power loss and signal distortion in fiber communications. FIG. 8 illustrates the stress-optic modulator locked to the laser output using a PDH locking circuit in accordance with an embodiment. The PZT-actuated ring modulator 802 is locked to the laser 801 in a PID locking loop 803. When an external signal 804 is applied to the laser 801, the locked modulator 802 can respond to the signal dithering and track the laser carrier. The scope at the output port 805 can record the optical level fluctuation (orange) with the signal dithering in the laser signal (blue). The PDH error signal (shown in the inset) indicates the deviation between the resonator resonance and the laser tone. The PDH servo uses the error signal to control the PZT actuator 802 to lock the resonance to the laser carrier. To demonstrate the tracking function, the filter output 806 can be measured in response to a sinusoidal varying output wavelength and to a step response output wavelength shift of the tunable laser. The sinusoidally varying or step input signal (Vᵢₙ) can be applied to the optical frequency modulation control input of a Velocity TLB-6730 laser.

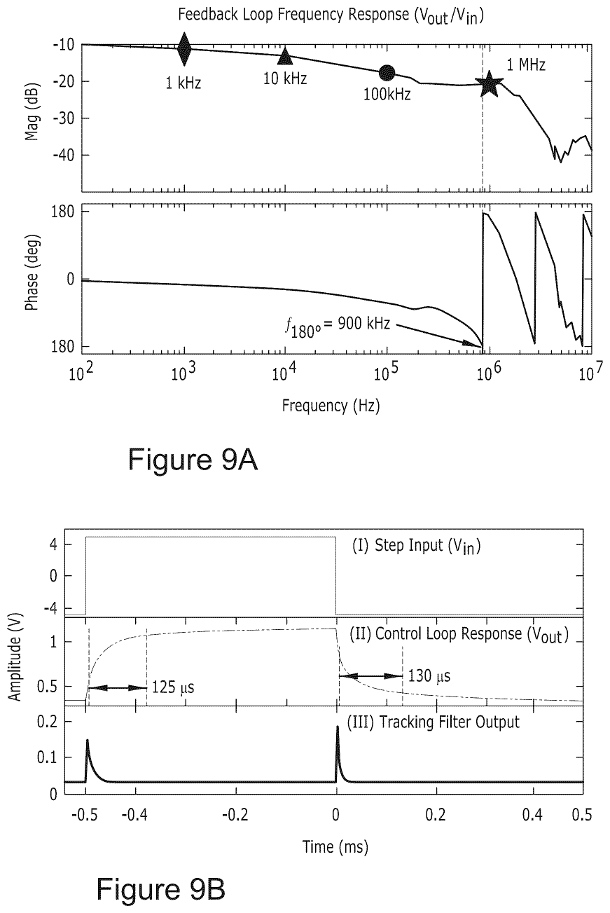

FIGS. 9A and 9B illustrate the frequency response of the sinusoidal and step input signal respectively in accordance with an embodiment. The small signal frequency response of the tracking loop, including the individual responses of the laser, the PZT actuator, the photodetector and the PID loop, is characterized by Vₒᵤₜ/Vᵢₙ as shown in FIG. 9A. The bandwidth of the system, characterized at the 180° phase lag point, is f_{180°}=0.9 MHz and is mainly limited by the tunable laser bandwidth wavelength control of approximately 1 MHz. As shown in right-side of FIG. 9A, within the lock bandwidth, the optical level at the tracking filter output of the signal is maintained at a constant value (within 3% at 1 KHz and 10 kHz) with the external signal dithering. When the applied signal reaches 1 MHz, which is near a bandwidth resonance, the optical output of the filter fluctuates.

FIG. 9B illustrates the tracking system step response. The blue trace is the applied step signal (1 kHz square waveform) to the laser frequency tuning, and the red trace is the control loop response measured at the input to the PZT actuator. The tracking filter output shows the stabilization time (90% to 10%) in response to the step wavelength change at the input. The time to stabilize the lock is approximately 130 μs and the settling time is approximately 8 μs. With proper bandwidth design, this integrated PZT modulator can be used to monitor and track the signal carrier drift and filter the desired signals in communication links.

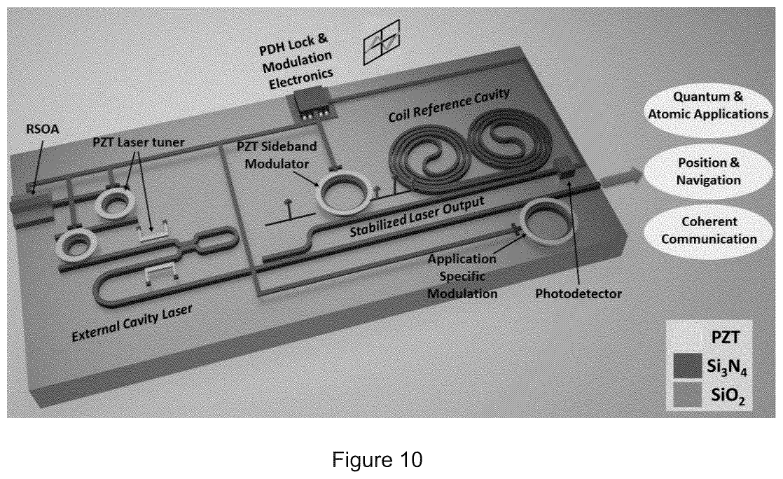

Many embodiments implement the PZT modulator and the silicon nitride waveguide in a frequency stabilized laser. FIG. 10 illustrates PZT-actuated modulators for control functions in an external cavity laser (ECL) in accordance with an embodiment of the invention. The PZT actuator can be used to tune and control the ECL, and generate sidebands to further stabilize the laser fluctuation by PDH locking to an ultra-high Q reference cavity. The stabilized output can be modulated (optional) based on specific applications. With this potential application, the low-power tuning PZT actuator can be used to fine tune a silicon nitride dual-resonators Vernier laser and carrier lock the laser to an on-chip coil reference cavity using the double sideband modulator and a PDH lock loop. The stabilized laser output can be further modulated for locking to applications including (but not limited to) quantum and atomic applications, position and navigation, and coherent communications.

### Example Devices Including Stress-Optic Modulators

The stress-optic modulators described herein may be utilized in various types of photonic devices. For example, a photonic device may include one or more of the stress-optic modulators. The photonic device may include one, two, or three stress-optic modulators. The photonic device may include one or more buses. For example, the photonic device may include one or two buses. The photonic device may include one or more heaters which further modulate the stress-optic modulators.

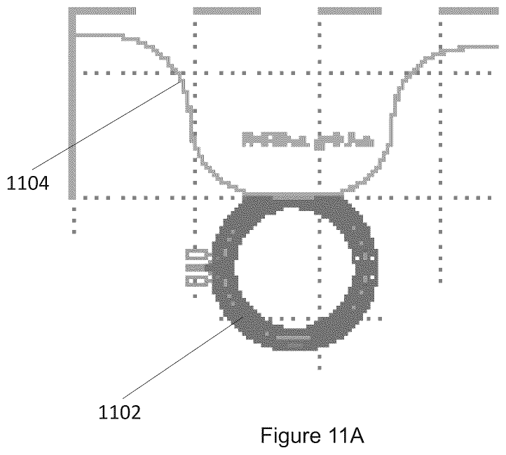

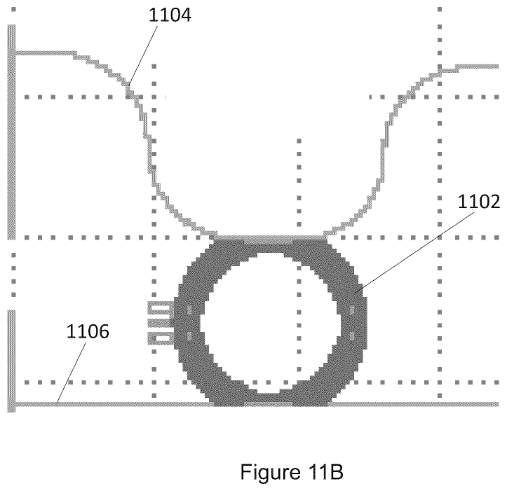

FIG. 11A is an example layout of a photonic device including a single stress-optic modulator in accordance with an embodiment of the invention. A stress optic modulator 1102 may be connected to a single bus 1104. FIG. 11B is an example of a photonic device including a single stress-optic modulator in accordance with an embodiment of the invention. The stress-optic modulator 1102 may include two buses, a first bus 1104, and a second bus 1106.

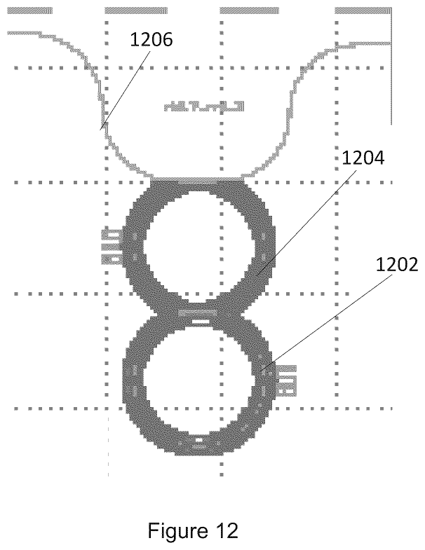

FIG. 12 is an example layout of a photonic device including two stress-optic modulators in accordance with an embodiment of the invention. A first stress-optic modulator 1202 may be connected to a second stress-optic modulator 1204. The second stress-optic modulator 1204 may be connected to a single bus 1206.

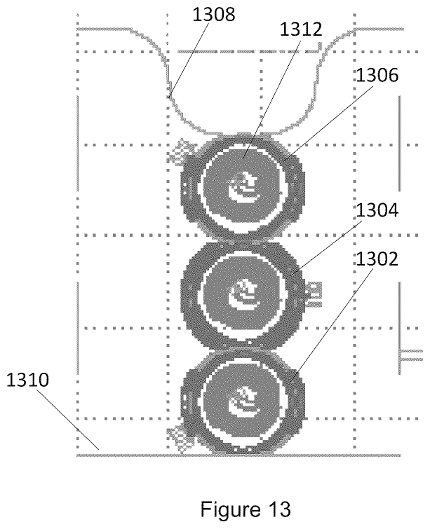

FIG. 13 is an example layout of a photonic device including three stress-optic modulators in accordance with an embodiment of the invention. A first stress-optic modulator 1302 may be connected to a second stress-optic modulator 1304 which may be connected to a third stress-optic modulator 1306. The third stress-optic modulator 1306 may be connected to a first bus 1308 and the first stress-optic modulator 1302 may be connected to a first bus 1310. The photonic device may also include thermal tuners 1312 made of Pt metal which may assist with strong static tuning.

For example, photonic devices including multiple stress-optic modulators, one stress-optic modulator may be tuned to align the frequency with the one or more of the other stress-optic modulators such as to tune for imperfections in the fabrication of the modulators.

In some embodiments, static tuning may be provided in which a DC signal is provided to one or more of the stress-optic modulators. In some embodiments, an RF or AC signal may be provided to one or more of the stress-optic modulators.

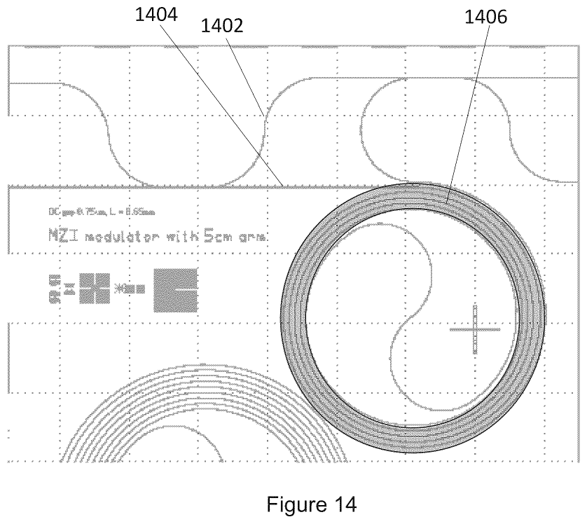

One particular example including stress-optic modulators includes a Mach-Zehnder interferometer (MZI) modulator. FIG. 14 is a layout of an example MZI modulator including a stress-optic modulator in accordance with an embodiment of the invention. A first arm 1402 may be connected to a second arm 1404. The second arm 1404 may be connected to a stress-optic modulator 1406. The path length of the second arm 1404 may be altered based on the voltage applied to the stress-optic modulator 1406 such that the MZI modulator is tunable by the stress-optic modulator 1406.

### DOCTRINE OF EQUIVALENTS

As can be inferred from the above discussion, the above-mentioned concepts can be implemented in a variety of arrangements in accordance with embodiments of the invention. Accordingly, although the present invention has been described in certain specific aspects, many additional modifications and variations would be apparent to those skilled in the art. It is therefore to be understood that the present invention may be practiced otherwise than specifically described. Thus, embodiments of the present invention should be considered in all respects as illustrative and not restrictive.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately,” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

What is claimed is:

1. A stress-optical modulator comprising:
a circular piezo-electric actuator; and
a ring waveguide separated from the circular piezo-electric actuator by a top cladding layer,
wherein the circular piezo-electric actuator is offset from the ring waveguide such that a first circular portion of the circular piezo-electric actuator is located on the outside of the ring waveguide and a second circular portion of the circular piezo-electric actuator is located on the inside of the ring waveguide,
wherein the circular piezo-electric actuator is configured to change the guiding properties of the ring waveguide based on the voltage applied to the circular piezo-electric actuator by inducing strain through the top cladding layer to change the optical properties of the ring waveguide.

2. The stress-optical modulator of claim 1, wherein the piezo-electric actuator comprises a piezo-electric material positioned between two electrodes.

3. The stress-optical modulator of claim 2, wherein the piezo-electric material comprises lead zirconate titanate (PZT) or aluminum nitride.

4. The stress-optical modulator of claim 3, wherein the two electrodes comprise platinum.

5. The stress-optical modulator of claim 2, wherein one of the two electrodes contact the top cladding layer.

6. The stress-optical modulator of claim 1, wherein the inside edge of the first circular portion and the second circular portion is completely offset from all portions of the ring waveguide.

7. The stress-optical modulator of claim 6, wherein the first circular portion and the second circular portion does not overlap with the ring waveguide in a direction perpendicular to a major extending direction of the ring waveguide.

8. The stress-optical modulator of claim 1, further comprising:
a substrate; and
a bottom cladding layer positioned on the substrate, wherein the ring waveguide is supported by the bottom cladding layer.

9. The stress-optical modulator of claim 8, wherein the ring waveguide has a refractive index which is higher than the top cladding layer and the bottom cladding layer.

10. The stress-optical modulator of claim 9, wherein the top cladding layer has a refractive index which is different from the refractive index of the bottom cladding layer.

11. The stress-optical modulator of claim 1, wherein the ring waveguide is connected through a bus waveguide to a laser.

12. The stress-optical modulator of claim 11, wherein the ring waveguide is connected through one or more optical components to the laser.

13. The stress-optical modulator of claim 11, wherein the ring waveguide and the bus waveguide comprises a same material such that the ring waveguide and bus waveguide include a high quality factor (Q) resonator.

14. The stress-optical modulator of claim 11, wherein the ring waveguide, the bus waveguide, and the laser are planar.

15. The stress-optical modulator of claim 1, wherein the piezo-electric actuator covers less than 50% of the ring waveguide.

16. The stress-optical modulator of claim 1, wherein the circular piezo-electric actuator is offset from the ring waveguide by an offset distance from 2 μm to 5 μm.

17. The stress-optical modulator of claim 1, wherein an input signal to the piezo-electric actuator is a DC signal, an AC signal, or a broadband DC to AC signal.

18. The stress-optical modulator of claim 1, wherein the ring waveguide comprises a material selected from the group consisting of a material with a third order (Kerr) nonlinearity, a material with a second order nonlinearity, a material of with anomalous material and resonator dispersion, and a material of with normal material and resonator dispersion.

19. The stress-optical modulator of claim 1, wherein the ring waveguide has a shape selected from the group consisting of: a ring resonator, a loop resonator, a coil resonator, and a racetrack resonator.

20. The stress-optical modulator of claim 1, wherein the ring waveguide comprises a material selected from the group consisting of: silicon nitride, tantalum pentoxide, alumina oxide, and aluminum nitride.

21. The stress-optical modulator of claim 1, wherein the piezo-electric actuator comprises PZT and the ring waveguide comprises silicon nitride, and the modulator functions at a wavelength selected from the group consisting of: a visible wavelength range of approximately 400 nm to 750 nm, a near IR from 700 nm to 2500 nm, and a mid IR from 2.5 μm to 25 μm.

22. The stress-optical modulator of claim 1, wherein the piezo-electric actuator comprises PZT and the ring waveguide comprises tantalum pentoxide or alumina oxide or aluminum nitride, and the modulator functions at a far-UV range from approximately 100 nm to 200 nm, a mid-UV from 200 nm to 300 nm, a near UV from 300 nm to 400 nm, and out to visible, near IR and mid-IR (400 nm to 2350 nm) and beyond.
